(19) United States
(12) Patent Application Publication
(10) Pub. No.: US 2008/0022029 A1
(43) Pub. Date: Jan. 24, 2008

(54) ELECTRICAL SIGNAL CONNECTION SYSTEM

(75) Inventors: Yao-jen Chang, Banciao City (TW); Ker-fu Bieh, Shulin City (TW)

Correspondence Address: MADSON & AUSTIN, 15 WEST SOUTH TEMPLE, SUITE 900, SALT LAKE CITY, UT, 84101, US

(73) Assignee: Benica Corporation, Shindian City (TW)

(21) Appl. No.: 11/626,019

(22) Filed: Jan. 23, 2007

(30) Foreign Application Priority Data
Jul. 20, 2006 (TW) 095212771

(51) Int. Cl. H05K 7/10; H01R 29/00

(52) U.S. Cl. 710/301; 439/43

(57) ABSTRACT

An electrical signal connection system including an electrical signal transferring module for transferring electrical data between an electrical memory card and an electrical device is provided. Each side of the electrical memory card has a set of data transmission pads, and each set of data transmission pad has a plurality of output pins and an identification pin. The electrical signal connection system includes at least a casing, a plurality of receiving ends, an identification receiving end, and a plurality of signal output ends. The plurality of receiving ends disposed at a first end of the casing, for electrically connecting to the plurality of output pins of the electrical memory card. The identification receiving end disposed within the first end of the casing, is used for electrically connecting to the identification pin of the electrical memory card. The plurality of signal output ends are disposed on a second end of the casing, and each signal output end being directly connecting to one of the plurality of the receiving ends.

### BACKGROUND OF THE INVENTION

1. Field of the Invention

The present invention relates to an electrical signal connection system, and more specifically, to an electrical signal connection system for use in various USB storage systems

2. Description of the Related Art

In recent years, traditional large-capacity memory cards for use in digital cameras, such as CF cards, are mostly-used SD standard. However, since mobile phones, Personal Digital Assistants (PDA), Global Positioning Systems (GPS), etc have become popular, the demands of small-capacity memory cards have expanded rapidly. With the increasing amount of digital cameras, mobile phones, portable video camcorder, MP3 players, and digital recording devices, the use of small-capacity memory cards increases.

Data inter-transmission among various electrical devices is realized by USB interface. For example, PCs can make a connection among various peripheral devices with different operating speeds in a simple way that, via USB interface, peripheral devices can transmit data under the control of PCs. However, without the PCs, the peripheral devices cannot operate via USB interface in such a convenient way. This is because that a peripheral device with USB interface is always as a slave device if the PC as a host device does not exist.

Although USB interface has become one of the standard specifications of linking the PC and the peripheral devices, USB Implementer's Forum (USB-IF) composed of Intel, Microsoft, Philips, etc, creates a new specification which provides additional functions such as peer-to-peer and low power-consumption in the original USB specification, named as USB On-The-Go (OTG).

With the OTG technology, one of peripheral devices can be set as a host device under a circumstance of no PC as a host device, so that data transmission between peripheral devices originally used as slave devices can still be realized.

In this way, all USB products have the independent operation abilities, and are not only restricted to playing the role of peripheral devices of a computer. For example, by means of USB interface of a digital camera, the digital camera is directly linked to a printer, which is able to print the pictures immediately via the OTG technology. Also, the data in the digital camera can also be transmitted to the removable hard disk of the USB interface via the OTG technology. By utilizing the OTG technology, an electrical peripheral device can not only serve as a slave device to communicate with a PC via the USB interface, but also the electrical peripheral device can serve as a host device to directly link with other slave devices. Therefore, the OTG technology brings more convenience to the users.

Therefore, a development of an electrical system combined OTG and USB standards is a trend in the industry.

### SUMMARY OF INVENTION

According to the claimed invention, an electrical signal connection system comprising an electrical signal transferring module for transferring electrical data between an electrical memory card and an electrical device is provided. Each side of the electrical memory card has a set of data transmission pads, and each set of data transmission pad has a plurality of output pins and an identification pin. The electrical signal connection system comprises at least a casing; a plurality of receiving ends disposed at a first end of the casing, for electrically connecting to the plurality of output pins of the electrical memory card; an identification receiving end disposed within the first end of the casing, for electrically connecting to the identification pin of the electrical memory card; and a plurality of signal output ends disposed on a second end of the casing, each signal output end being directly connecting to one of the plurality of the receiving ends.

According to the claimed invention, an electrical signal connection system comprises an electrical memory card comprising a set of data transmission pads, each set of data transmission pad having a plurality of output pins and an identification pin; an electrical signal transferring module for accessing electrical data stored in the electrical memory card; a plurality of receiving ends for electrically connecting to the plurality of output pins of the electrical memory card; an identification receiving end for electrically connecting to the identification pin of the electrical memory card; and an electrical device comprising an accessing controller for accessing data stored in the electrical memory card via the plurality of receiving ends.

According to the claimed invention, an electrical signal connection system comprising an electrical signal transferring module for transferring electrical data between a first electrical device and a second electrical device is provided. The first electrical device comprises a plurality of output pins and an identification pin. The electrical signal transferring module comprises a first casing; a plurality of receiving ends disposed within the first casing, for electrically connecting to the plurality of output pins of the first electrical device; an identification receiving end disposed within the first casing, for electrically connecting to the identification pin of the first electrical device; and a second casing; and a plurality of signal output ends disposed within the second casing, each signal output end being directly connecting to one of the plurality of the receiving ends.

According to the claimed invention, an electrical signal connection system comprising an electrical signal transferring module for transferring electrical data between a first electrical device and a second electrical device is provided. The first electrical device comprises a plurality of output pins and an identification pin. The electrical signal transferring module comprises a plurality of receiving ends for electrically connecting to the plurality of output pins of the first electrical device; an identification receiving end for electrically connecting to the identification pin of the electrical device; a plurality of signal output ends, each signal output end being directly connecting to one of the plurality of the receiving ends to electrically connect to the second electrical device; an identification signal output end for electrically connecting to the second electrical device; and a switch for controlling route of the identification receiving to determine a host/slave relationship between the first electrical device and the second electrical device.

These and other objectives of the present invention will become apparent to those of ordinary skilled in the art after reading the following detailed description of the preferred embodiment that is illustrated in the various figures and drawings

### BRIEF DESCRIPTION OF THE DRAWINGS

FIG. 1 shows an exploded diagram of an electrical connection system according to a preferred embodiment of the present invention.

FIG. 2 illustrates the electrical memory card of the electrical connection system.

FIG. 3 showing a side view of the electrical memory card depicted in FIG. 2.

FIGS. 4A and 4B show a first embodiment and a second embodiment of the electrical transferring module depicted in FIG. 1 respectively.

FIG. 5 shows an internal structure of the electrical transferring module.

FIG. 6 is cross section view along line 4-4′ in FIG. 4A.

FIG. 7 is a schematic diagram of the electrical memory card inserted into the electrical transferring module.

FIG. 8 illustrates the electrical memory card plugging into the electrical transferring module upside down.

FIG. 9 shows an internal structure of the electrical signal connection system according to a preferred embodiment of the present invention.

FIG. 10 shows an electrical signal connection system in accordance with a preferred embodiment of the present invention.

FIG. 11 is cross section view along line 10-10′ depicted in FIG. 10.

FIG. 12 is cross section view along line 10″-10′″ depicted in FIG. 10.

FIG. 13 shows a diagram of an electrical signal connection system according to a preferred embodiment of the present invention.

FIG. 14 is cross section view along line 13-13′ depicted in FIG. 13.

FIG. 15 is cross section view along line 13″-13′″ depicted in FIG. 13.

### DETAILED DESCRIPTION OF THE PREFERRED EMBODIMENT

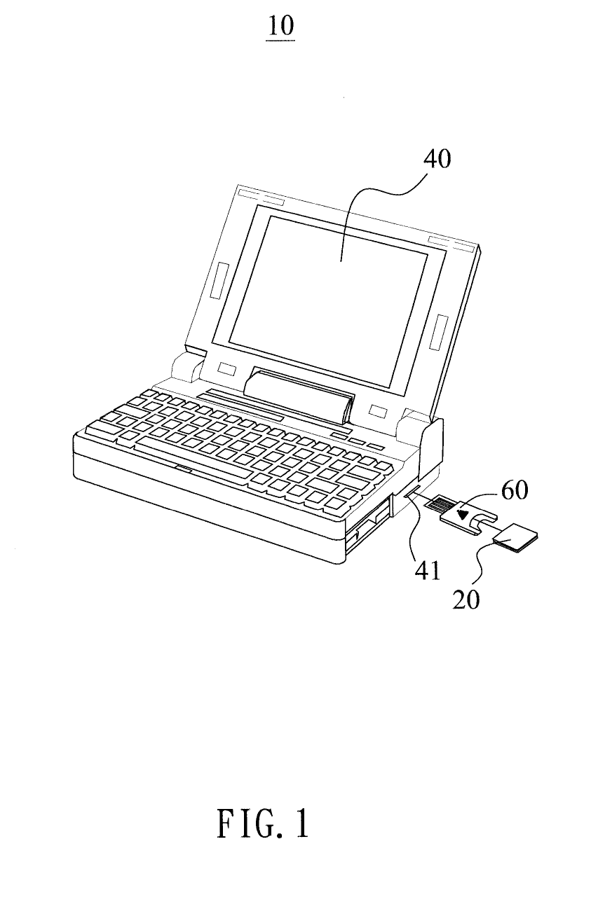

Please refer to FIG. 1, which shows an exploded diagram of an electrical connection system 10 according to a preferred embodiment of the present invention. The electrical connection system 10 comprises an electrical memory card 20, an electrical device 40, and an electrical transferring module 60. In this embodiment, the electrical transferring module 60 is an adapter capable of plugging into a slot 41 of the electrical device 40, for example an USB (Universal Serial Bus) interface port in comply with OTG specification. The electrical device 40, for example a notebook computer or a desktop computer, comprises a controller, e.g. a central processing unit (CPU), for controlling an operation of accessing data stored in the electrical memory card 20.

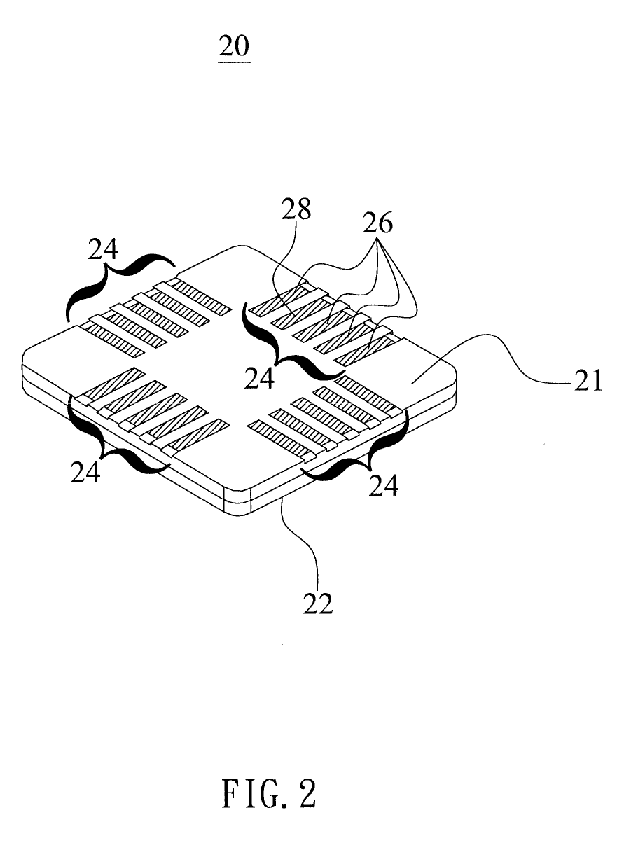

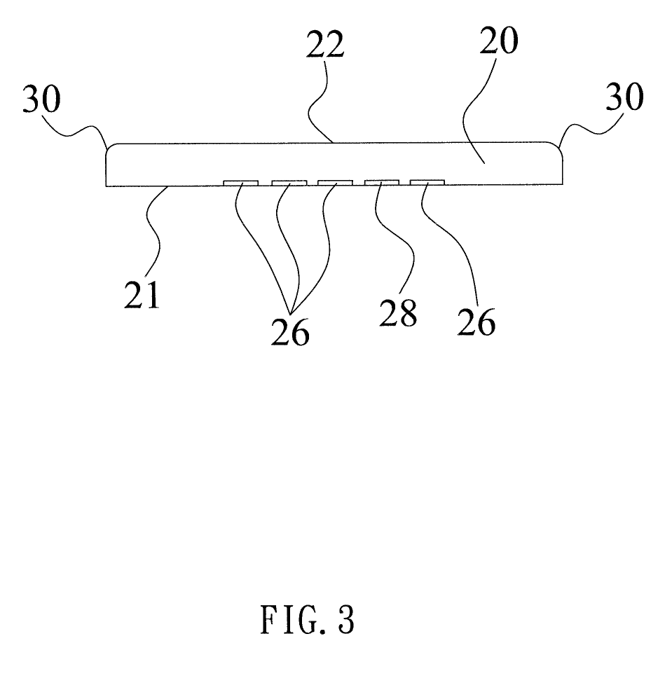

Please refer to FIG. 2 illustrating the electrical memory card of the electrical connection system 10, and FIG. 3 showing a side view of the electrical memory card depicted in FIG. 2. The electrical memory card 20 comprises a flash memory, a memory controller, and an OTG controller (not shown) for data storage and transmission. The electrical memory card 20 has a first surface 21 and a second surface opposite to the first surface disposed on four edges of the first surface of the electrical memory card 20, each data transmission pad 24 contains a plurality of output pins 26 and an identification (ID) pin 28 in comply with USB On-The-Go standard. Further, the plurality of output pins 26 comprises two data transmission pins D+, D−, and two supply voltage pins V_{BUS}, Gnd; the ID pin 28 is used for not only identifying host/slave devices, but also delivering other designated signals. The electrical memory card 20 comprises one or more positioning regions 30, for example four positioning regions shown in the embodiment. The four positioning regions 30, shaped to a cut-off corner as shown in FIG. 3, are respectively located at four corners of the second surface 22. In another embodiment, the positioning region 30 disposed on any corner of the first surface 21 is also allowed.

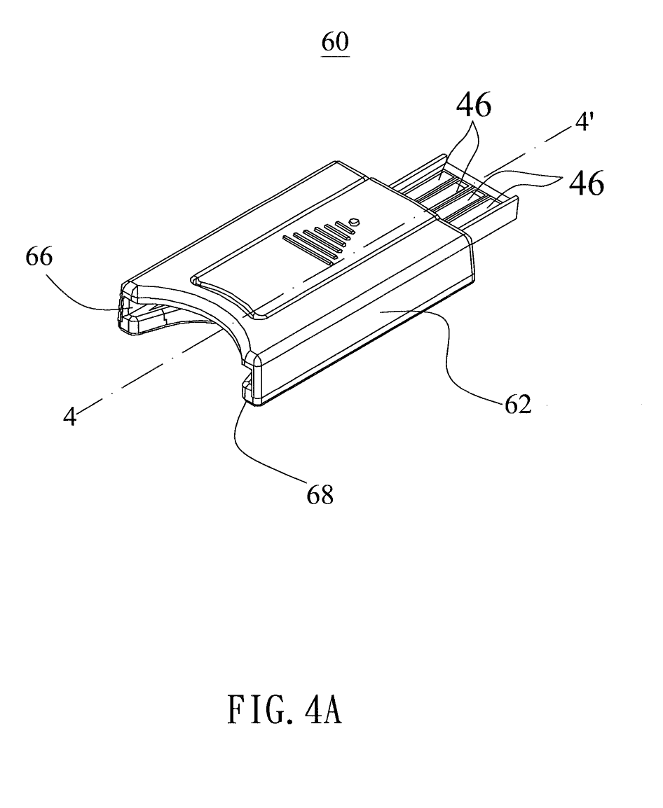

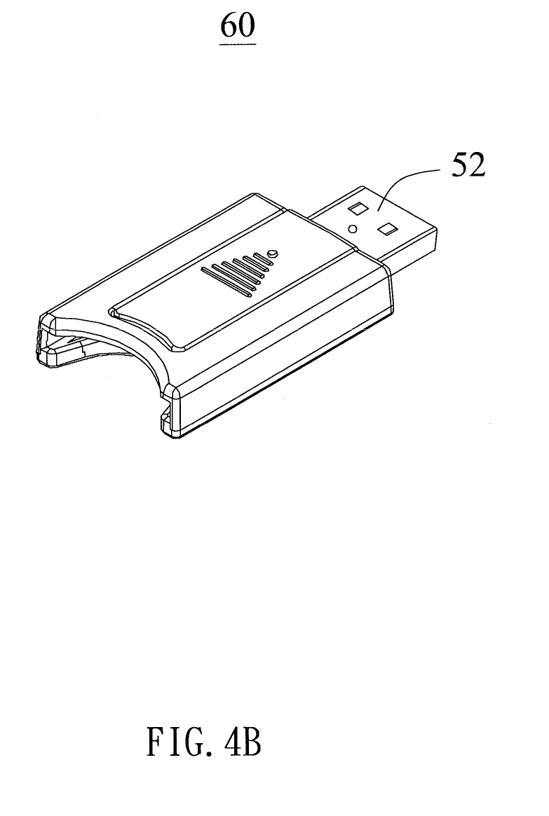

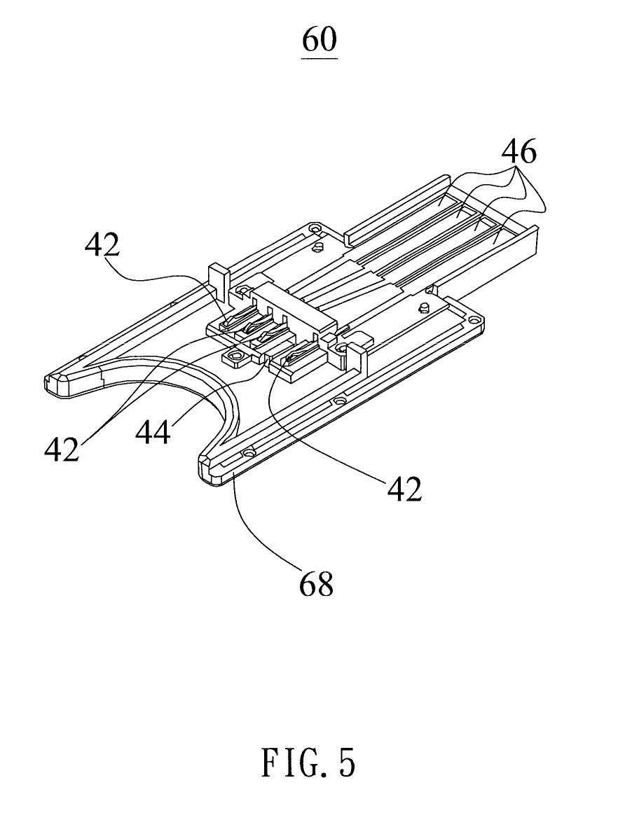

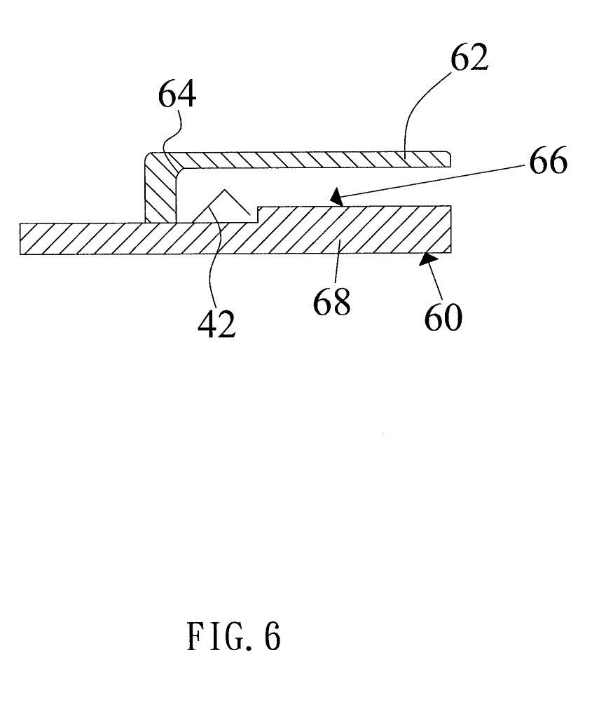

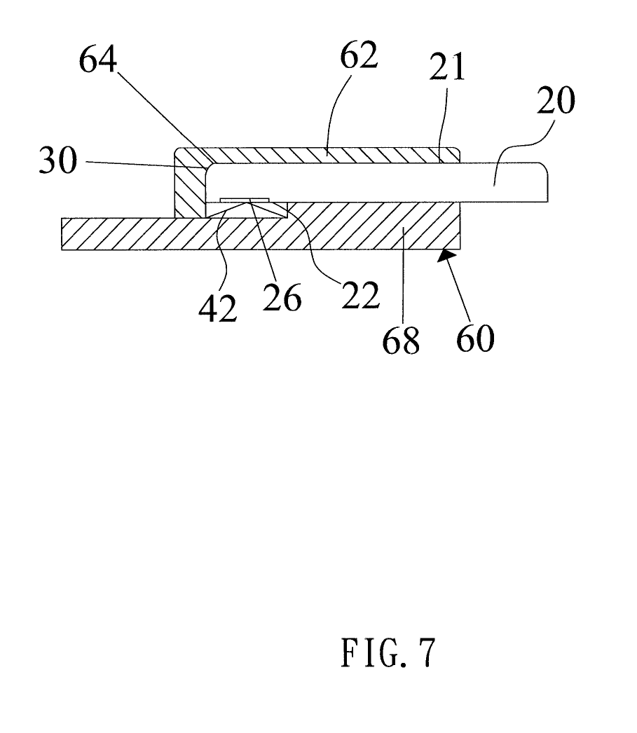

Please refer to FIGS. 4A and 4B, which show a first embodiment and a second embodiment of the electrical transferring module 60 depicted in FIG. 1. A discrepancy between the two embodiments is that the electrical transferring module 60 depicted in FIG. 4B has a metal casing 52 enclosing a plurality of signal output ends 46 drawn in FIG. 4A for EMI-proofing, as similar as a standard USB connector. For brevity, the electrical transferring module 60 shown in FIG. 4A is as an example for detailed explanation. The electrical transferring module 60 comprise an upper shell 62 and a bottom shell 68, each having a half-circle-shaped recess for manually attaching or detaching the electrical memory card 20 on the electrical transferring module 60. The two casings 62, 68 are engaged to form a track 66. The plurality of receiving ends 42 and an ID receiving end 44 are accommodated within the engaged two casings 62, 68, and the track 66 is used for guiding the electrical memory card 20 to be inserted (As shown in FIGS. 6 and 7). The plurality of signal output ends 46, set at the front of the casing 68, can be inserted into USB ports 41 (as shown in FIG. 1) of the electrical device 40. The plurality of receiving ends 42 and the ID receiving end 44 are in comply with the standard of USB On-The-Go specification in characteristic of 5 specific function pins. Furthermore, the plurality of receiving ends 42 of 4 pins are in comply with the standard USB specification, and can be electrically connected to the plurality of output pins 26 (4 pins) of the electrical memory card 20. The ID receiving end 44 can be electrically connected to the ID pin 28 of the electrical memory card 20. The plurality of signal output ends 46 are in comply with the standard USB specification. Each signal output end 46 can be directly connected a corresponding receiving end 42, without passing through any additional circuit for signal processing or signal transforming. By contrast, the ID receiving end 44 is not connected to any signal output end. In other words, according to the embodiment of the electrical transferring module 60, the plurality of receiving ends 42 are used for receiving data signal from the two data transmission pins D+, D−, and two supply voltage pins V_{BUS}, Gnd of the electrical memory card 20, while the ID receiving end 44 is open circuit, i.e., no electrical signal is delivered by way of the signal output end 46. Or, in another embodiment, the ID receiving end 44 can be connected to the ID pin 28 which is connected to the electrical device. In this way, by verifying whether the ID receiving end 44 is connected to the ID pin 28 or not, a host/slave relationship between the electrical device and the electrical memory card is accordingly determined. Moreover, as shown in FIG. 6, and 7, the electrical transferring module 60 further comprises a plurality of engaging portion 64 formed on the upper shell 62. The plurality of engaging portion 64 are exactly matched the plurality of positioning regions 30 when the electrical memory card 20 is inserted accurately into the electrical transferring module 60.

Please refer to FIG. 6 which is cross section view along line 4-4′ in FIG. 4A, in conjunction to FIG. 7 which is a schematic diagram of the electrical memory card 20 inserted into the electrical transferring module 60. Once the electrical memory card 20 is inserted into the electrical transferring module 60, the plurality of receiving ends 42 are electrically connected to the plurality of output pins 26 of the electrical memory card 20. Thereafter, the electrical transferring module 60 can be plugged into the electrical device 40 illustrated in FIG. 1, an accessing controller of the electrical device 40 can access electrical data stored in the electrical memory card 20 and deliver to a memory of the electrical device 40. As an example, the electrical device 40, e.g. a notebook computer as shown in FIG. 1, comprises a slot 41 which may be a standard USB interface transmission port, and an accessing controller which may be a central processing unit of the notebook computer. After the electrical memory card 20 is inserted into the electrical transferring module 60, and the plurality of receiving ends 42 contacts to the plurality of output pins 26 of the electrical memory card 20, the electrical transferring module 60 can be plugged into the USB port of the electrical device 40. Despite the ID receiving end 44 is not electrically connected to the accessing controller of the electrical device 40 by route of the signal output ends 46, the electrical memory card 20 still functions as a USB memory card on account of all the plurality of output pins 26 and the plurality of receiving ends 42 in consistent with USB specification. Accordingly, an electrical connection between the electrical memory card 20 and the electrical device 40 is realized by using USB specification signal.

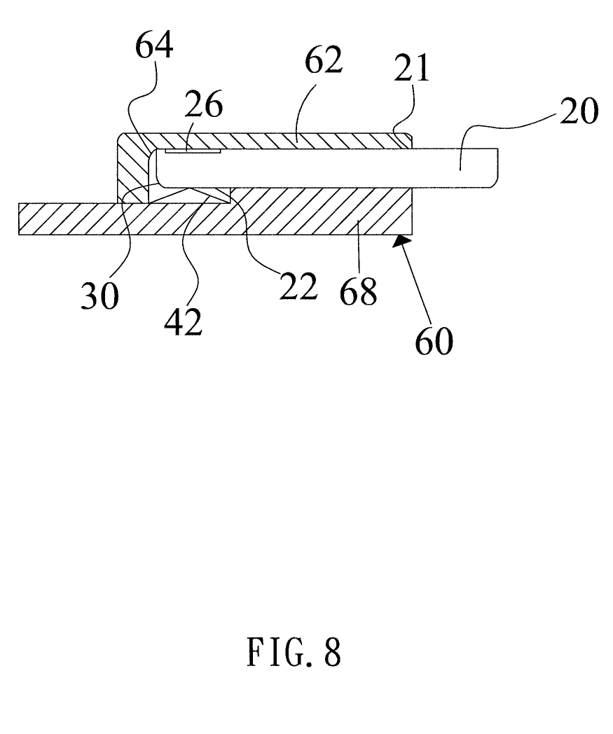

Please refer to FIG. 8 illustrating the electrical memory card 20 plugging into the electrical transferring module 60 upside down. When the electrical memory card 20 is plugged into the electrical transferring module 60 upside down through the track 66, meanwhile, the second surface 22 directly contacts with the plurality of receiving ends 42, the positioning region 30 of the electrical memory card 20 is not matched with the engaging member 64 of the electrical transferring module 60, causing the electrical memory card 20 incompletely plugging into the electrical transferring module 60. In this way, the user must draw out the electrical memory card 20 and re-position the electrical memory card 20 into the electrical transferring module 60.

In this embodiment, the positioning region 30 is shaped as an arc or a recess, and the engaging member 64 can be a column. The design for verifying whether the electrical memory card is correctly inserted into the electrical transferring module 60, which is realized by an exact engagement of the positioning region 30 and the engaging member 64, belongs to the scope the present invention.

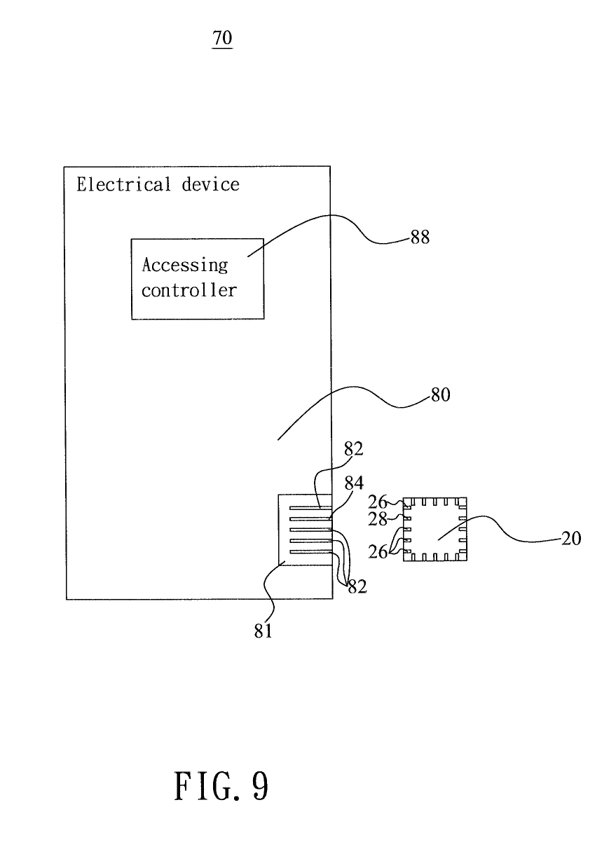

Please refer to FIG. 9, which shows an internal structure of the electrical signal connection system 70 according to a preferred embodiment of the present invention. Differing from the electrical connection system 10, the electrical transferring module of the electrical connection system 70 is built in a slot device 81 having a card push-out mechanism of an electrical device 80. The slot device 81 comprises a plurality of receiving ends 82 and an ID receiving end 84. The plurality of receiving ends 82 and the ID receiving end 84 are in comply with the standard of USB On-The-Go specification in characteristic of 5 specific function pins. Furthermore, the plurality of be electrically connected to the plurality of output pins 26 (4 pins) of the electrical memory card 20, i.e. the two data transmission pins D+, D−, and the two supply voltage pins V_{BUS}, Gnd. Also, the ID receiving end 84 is for electrically connected to the ID pin 28. The electrical device 80 further comprises an accessing controller 88 for accessing data of the electrical memory card 20. The accessing controller 88 determines a host/slave relationship between the electrical device 80 and the electrical memory card 20 based on whether the ID receiving end 84 contacts with the ID pin 28. If the accessing controller 88 fails to read signal from the ID pin 28 which implies that the ID receiving end 84 do not contact with the ID pin 28, the electrical memory card 20 serves as a slave device and the electrical device 80 serves as a host device. The electrical device 80 can be a convenient personal computer, a portable media player, a global positioning system (GPS), a mobile phone, a personal digital assistant (PDA), a digital camera, a digital camcorder, or other electrical devices capable of storing digital data. The accessing controller 88 can be a central processing unit (CPU) or other chips capable of controlling the operation of accessing data.

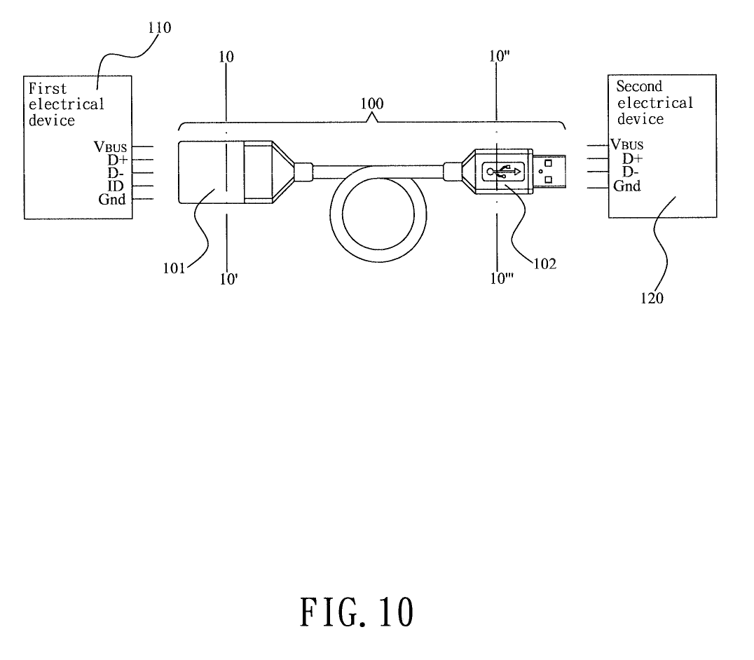

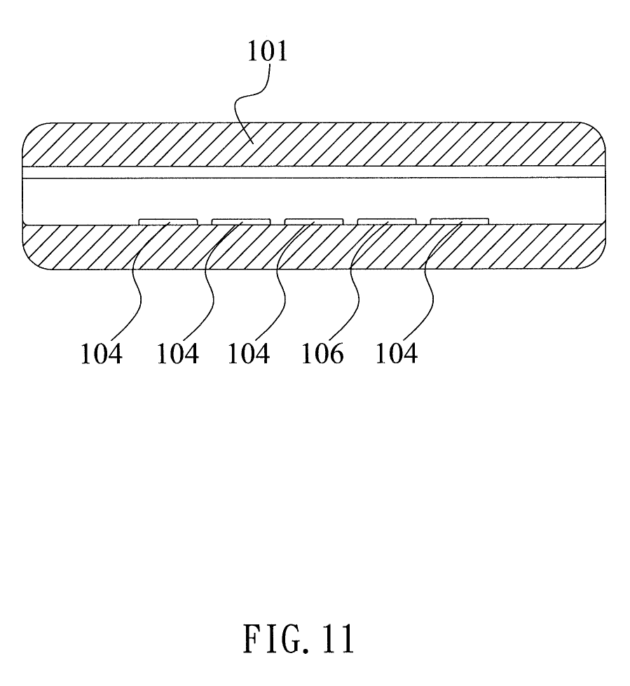

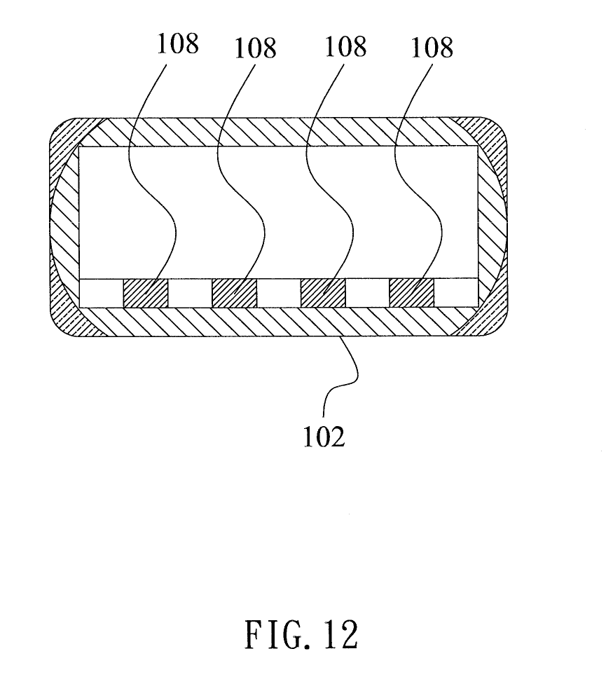

Please refer to FIG. 10, which shows an electrical signal connection system in accordance with a preferred embodiment of the present invention. The electrical linking system contains an electrical transforming module 100, a first electrical device 110, and a second electrical device 120. In this embodiment, the electrical transferring module 100, which is used for transmitting electrical data signal between the first electrical device 110 and a second electrical device 120, can be a cable having two plugs at two ends. The first electrical device 110 comprises a plurality of output pins 112 and an identification pin 114, all are in comply with USB OTG interface specification. The electrical transferring module 100 comprises a first casing 101 and a second casing 102 respectively formed on the two ends. As shown in FIGS. 11 and 12, a plurality of receiving ends 104 and an ID receiving end 106 within the first casing 101 complies with USB OTG interface specification. A plurality of signal output ends 108 are within the second casing 102 and each signal output end 108 is electrically connected to one of a plurality of receiving end 104, whereas the ID receiving end 106 is not electrically connected to any signal output end 108. The plurality of receiving ends 104 and the plurality of signal output ends 1 are connected with wires. Noted that the receiving ends 104 and the signal output ends 108 of the electrical signal transferring module 100, the plurality of output pins 112 of the first electrical device 110 are all in comply with USB interface specification.

When a data transmission between the first electrical device 110 and the second 120 is desired, the first casing 101 of the electrical transferring module 100 is plugged into the first electrical device 110, and the second casing 102 of the electrical transferring module 100 is plugged into the second electrical device 120. At this moment, the two data transmission pins D+, D−, and the two supply voltage pins V_{BUS}, Gnd of the first electrical device 110 are electrically connected to the plurality of output ends 104, while the plurality of the signal output ends 108 are electrically connected to the second electrical device 120. In other words, the data stored in the first electrical device 110 can be transmitted to second electrical device 120 via the electrical transferring module 100. Noted that, as shown in FIGS. 10 and 11, the first casing 101 is an OTG female connector, but an OTG male connector is also allowed. It should be understood to the ordinary skilled person in the art that the invention is not limited to the embodiments. For example, the second casing 102 can be designed as various male/female connector consistent with USB specification, such as USB Mini-A interface, USB A interface, USB B interface, USB Mini-B interface, USB Mini-AB interface and so on.

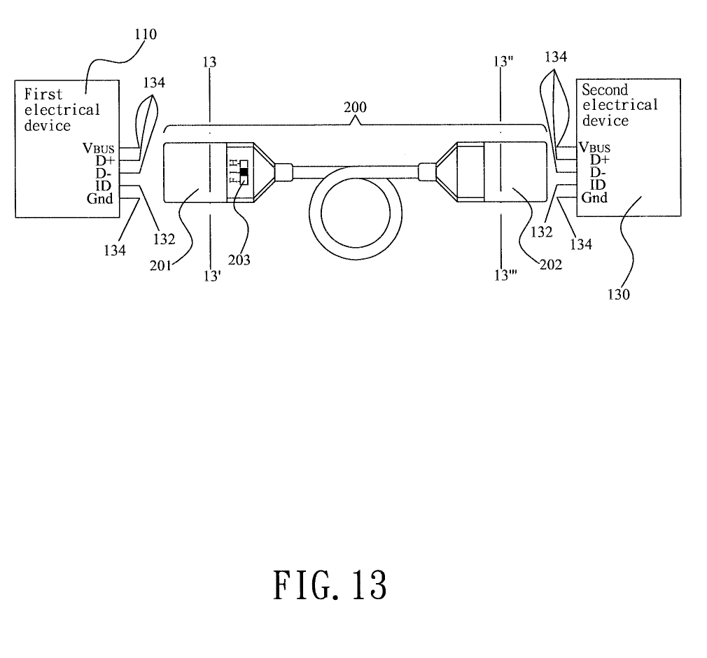

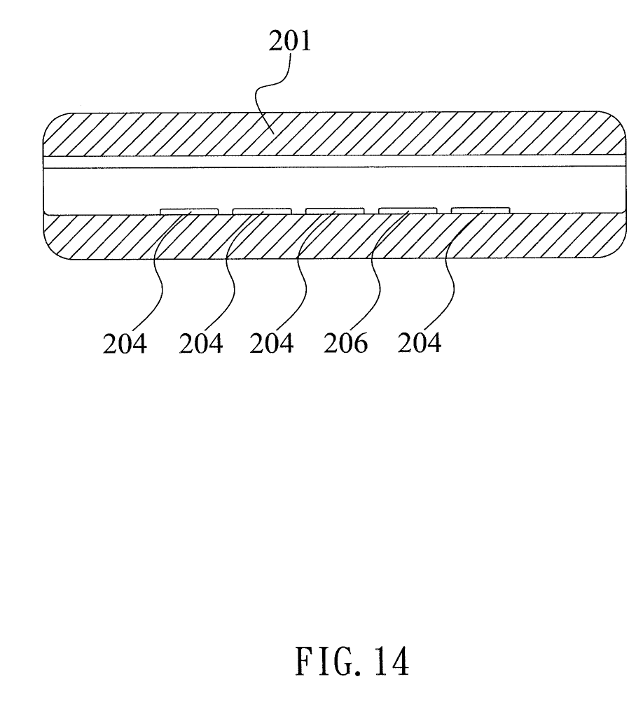

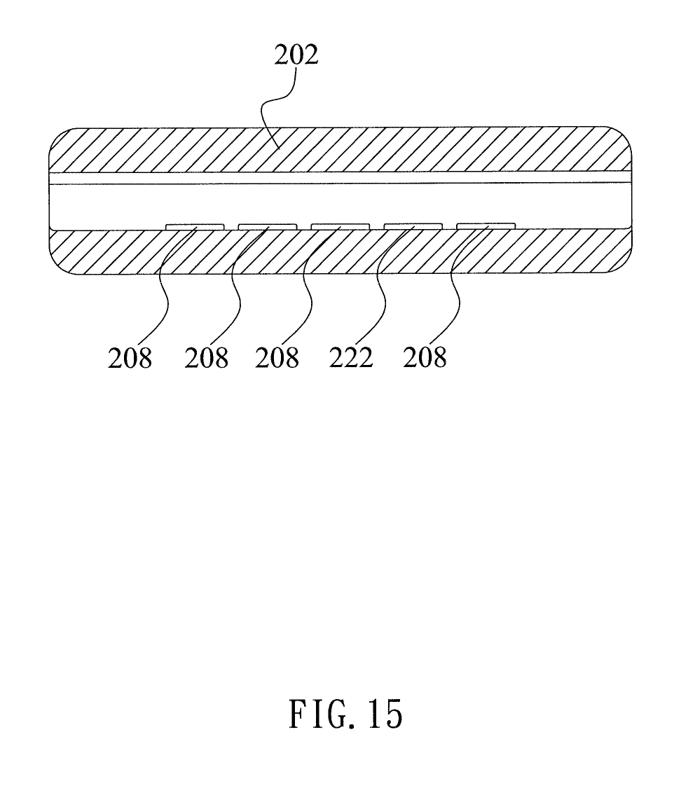

Please refer to FIGS. 13, 14, 15. FIG. 13 shows a diagram of an electrical signal connection system which comprises an electrical transferring module, a first electrical device and a second electrical device. The electrical transferring module 200, which is used for transmitting electrical data signal between the first electrical device 110 and a second electrical device 120, can be a cable having two plugs at two ends. The first electrical device 110 comprises a plurality of output pins 112 and an identification pin 114, all are in comply with USB OTG interface specification. The electrical transferring module 200 comprises a first casing 201 and a second casing 202 respectively formed on the two ends. As shown in FIG. 14, a plurality of receiving ends 204 and an ID receiving end 206 within the first casing 201 complies with USB OTG interface specification, and a switch 203 is also set on the first casing 201. As shown in FIG. 15, a plurality of signal output ends 208 and an ID signal output end are within the second end 204 with wires. Noted that, the receiving ends 204 and the signal output ends 208 of the electrical signal transferring module 200, the plurality of output pins of the electrical device 110, 120 are all in comply with USB interface specification.

When a data transmission between the first electrical device 110 and the second 120 is desired, the first casing 201 of the electrical transferring module 200 is plugged into the first electrical device 110, and the second casing 202 of the electrical transferring module 200 is plugged into the second electrical device 120. The switch 203 provides three operation modes, e.g. Floating mode (labeled as “F” on the switch 203), Identification mode (labeled as “I” on the switch 203) and Host mode (labeled as “H” on the switch 203). Under floating mode, the ID receiving end 206 do not electrically connects to any signal output end, and thus forms an open circuit, so that the first electrical device 110 serves as a slave device, while the second device 120 serves as a host device 120. Accordingly, the second electrical device 120 is able to control data transmission of the first electrical device 110. Alternately, under host mode, the Id receiving end 206 is grounded, so that the first electrical device 110 serves as a host device and the second electrical device 120 serves as a slave device. Accordingly, the first electrical device 110 is able to control data transmission of the second electrical device 120. Under Identification mode, the ID receiving end 206 is connected to an ID signal output end 222. Under this circumstance, the first electrical device 110 can transmit data to the second electrical device 120 via not only the receiving ends 204 and the signal output ends 208, but also the ID receiving end 206 and the ID signal output end 222. In this way, a speed of data transmission between the first electrical device 110 and the second electrical device 120 increases. In contrast to the electrical transferring module 100 depicted in FIG. 10, both sides of the electrical transferring module 200 are consistent with the USB OTG interface specification. Despite, as shown in FIGS. 14 and 15, the first casing 201 and the second casing 202 are OTG female connectors, either the first casing 201 or the second casing 202 can be designed as an OTG male connectors.

Each of the electrical devices 110, 120 can be a convenient personal computer, a digital assistant (PDA), a digital camera, a digital camcorder, or other electrical devices capable of storing digital data.

In contrast to prior art, the present invention electrical signal connection system can be applied in not only traditional USB interface specification but also novel OTG specification, and achieves an improvement of data storage and transmission.

The present invention has been described with reference to certain preferred and alternative embodiments which are intended to be exemplary only and not limited to the full scope of the present invention as set forth in the appended claims. Accordingly, the scope of the invention shall be determined only by the appended claims and their equivalents.

What is claimed is:

1. An electrical signal connection system comprising an electrical signal transferring module for transferring electrical data between an electrical memory card and an electrical device, each side of the electrical memory card having a set of data transmission pads, each set of data transmission pad having a plurality of output pins and an identification pin, the electrical signal connection system comprising:
At least a casing;
a plurality of receiving ends disposed at a first end of the casing, for electrically connecting to the plurality of output pins of the electrical memory card;
an identification receiving end disposed within the first end of the casing, for electrically connecting to the identification pin of the electrical memory card; and
a plurality of signal output ends disposed on a second end of the casing, each signal output end being directly connecting to one of the plurality of the receiving ends.

2. The electrical signal connection system of claim 1, wherein the plurality of receiving ends and the identification receiving end of the electrical signal transferring module are all in comply with USB OTG interface specification.

3. The electrical signal connection system of claim 1, wherein the plurality of output pins of the electrical memory card, and the plurality of signal output ends and the receiving ends of the electrical signal transferring module are all in comply with USB interface specification.

4. The electrical signal connection system of claim 1, wherein the electrical memory card comprises a first surface, a second surface opposite to the first surface, and at least a positioning region, each set of data transmission pads being disposed on each side of the first surface, and the at least a positioning region being disposed on each corner of the second surface.

5. The electrical signal connection system of claim 4, wherein the electrical signal transferring module has a first end and a second end, the first end of the electrical signal transferring module is capable of being electrically connected to the electrical memory card, and the second end of the electrical signal transferring module is capable of being plugged into a USB interface slot.

6. The electrical signal connection system of claim 5, wherein the electrical signal transferring module further comprises an upper shell and a bottom shell, each of the upper shell and the bottom shell comprises a half-circle-shaped recess, and when the upper shell and the bottom shell are engaged, a track is formed between the upper shell and the bottom shell so that the electrical memory card is capable of being inserted along the track.

7. The electrical signal connection system of claim 4, wherein the electrical signal transferring module further comprises an engaging member disposed within the casing, for preventing the electrical memory card from incorrectly positioning into the electrical signal transferring module.

8. The electrical signal connection system of claim 1, wherein the electrical device is a notebook computer, a convenient personal computer, or a desktop computer.

9. The electrical signal connection system of claim 1, wherein the electrical device is a personal digital assistant (PDA), a portable media player, a global positioning system (GPS) or a mobile phone.

10. The electrical signal connection system of claim 1, wherein the electrical device is a digital camera or a digital camcorder.

11. The electrical signal connection system of claim 1, wherein the identification end of the electrical signal transferring module is an open circuit.

12. An electrical signal connection system, comprising:
an electrical memory card comprising a set of data transmission pads, each set of data transmission pad having a plurality of output pins and an identification pin;
an electrical signal transferring module for accessing electrical data stored in the electrical memory card;
a plurality of receiving ends for electrically connecting to the plurality of output pins of the electrical memory card;
an identification receiving end for electrically connecting to the identification pin of the electrical memory card; and
an electrical device comprising an accessing controller for accessing data stored in the electrical memory card via the plurality of receiving ends.

13. The electrical signal connection system of claim 12, wherein the plurality of output pins and the identification pin of the electrical memory card, and the plurality of receiving ends and the identification receiving end of the electrical signal transferring module are all in comply with USB OTG interface specification.

14. The electrical signal connection system of claim 13, wherein the plurality of output pins of the electrical memory card, and the receiving ends of the electrical signal transferring module are all in comply with USB interface specification.

15. The electrical signal connection system of claim 12, wherein the electrical memory card comprises a first surface, a second surface opposite to the first surface, and each set of data transmission pads are disposed on each side of the first surface.

16. The electrical signal connection system of claim 15, wherein the electrical memory card further comprises at least a positioning region disposed on each corner of the second surface, and the electrical signal transferring module further comprises an engaging member, when the second surface of the electrical memory card contacts the plurality of receiving ends, the positioning regions are not engaged with the plurality of engaging member of the electrical signal transferring module to prevent the electrical memory card from incorrectly positioning into the electrical signal transferring module.

17. The electrical signal connection system of claim 12 wherein the electrical device is a notebook computer, a convenient personal computer, or a desktop computer.

18. The electrical signal connection system of claim 12 wherein the electrical device is a personal digital assistant (PDA), a portable media player, a global positioning system (GPS), or a mobile phone.

19. The electrical signal connection system of claim 12 wherein the electrical device is a digital camera or a digital camcorder.

20. The electrical signal connection system of claim 12 wherein the electrical signal transferring module is a slot device built in the electrical device.

21. An electrical signal connection system comprising an electrical signal transferring module for transferring electrical data between a first electrical device and a second electrical device, the first electrical device comprising a plurality of output pins and an identification pin, the electrical signal transferring module comprising:
a first casing;
a plurality of receiving ends disposed within the first casing, for electrically connecting to the plurality of output pins of the first electrical device;
an identification receiving end disposed within the first casing, for electrically connecting to the identification pin of the first electrical device; and
a second casing; and
a plurality of signal output ends disposed within the second casing, each signal output end being directly connecting to one of the plurality of the receiving ends.

22. The electrical signal connection system of claim 21, wherein the plurality of output pins and the identification pin of the first electrical device, and the plurality of receiving ends and the identification receiving end of the electrical signal transferring module are all in comply with USB OTG interface specification.

23. The electrical signal connection system of claim 22, wherein the plurality of output pins the second electrical device, and the plurality of receiving ends and the plurality of signal output ends of the electrical signal transferring module are all in comply with Universal Serial Bus (USB) interface specification.

24. The electrical signal connection system of claim 21, wherein the plurality of receiving ends are connected to the plurality of signal output ends with wires.

25. An electrical signal connection system comprising an electrical signal transferring module for transferring electrical data between a first electrical device and a second electrical device, the first electrical device comprising a plurality of output pins and an identification pin, the electrical signal transferring module comprising:
a plurality of receiving ends for electrically connecting to the plurality of output pins of the first electrical device;
an identification receiving end for electrically connecting to the identification pin of the electrical device; and
a plurality of signal output ends, each signal output end being directly connecting to one of the plurality of the receiving ends to electrically connect to the second electrical device;
an identification signal output end for electrically connecting to the second electrical device; and
a switch for controlling route of the identification receiving to determine a host/slave relationship between the first electrical device and the second electrical device.

26. The electrical signal connection system of claim 25, wherein the second electrical device comprises a plurality of output pins and an identification pin.

27. The electrical signal connection system of claim 26, wherein the identification signal output end of the electrical signal transferring module is used for contacting the identification pin of the second electrical device.

28. The electrical signal connection system of claim 27, wherein when the identification receiving end is an open circuit, the first electrical device is a slave device and the second electrical device is a host device.

29. The electrical signal connection system of claim 27, wherein when the identification receiving end is grounded, the first electrical device is a host device and the second electrical device is a slave device.

30. The electrical signal connection system of claim 27, wherein when the identification receiving end is electrically connected to the identification signal output end, the first electrical device is capable of transmit data to the second electrical device via the identification receiving end and the identification signal output end.

31. The electrical signal connection system of claim 27, wherein the plurality of output pins and the identification pin of the first electrical device, the plurality of output pins and the identification pin of the second electrical device, and the plurality of receiving ends, signal output ends, the identification receiving end and the identification receiving end of the electrical signal transferring module are all in comply with USB OTG interface specification.

32. The electrical signal connection system of claim 27, wherein the plurality of output pins of the first electrical device, the plurality of output pins of the second electrical device, and the plurality of receiving ends and the plurality of signal output ends of the electrical signal transferring module are all in comply with Universal Serial Bus (USB) interface specification.
